(19) United States
(12) Patent Application Publication
(10) Pub. No.: US 2026/0100237 A1
(43) Pub. Date: Apr. 9, 2026

(54) MEMORY DEVICE AND OPERATION METHOD THEREOF

(71) Applicant: Samsung Electronics Co., Ltd., Suwon-si (KR)

(72) Inventor: Taeyun Lee, Suwon-si (KR)

(21) Appl. No.: 19/266,755

(22) Filed: Jul. 11, 2025

(30) Foreign Application Priority Data
Oct. 7, 2024 (KR) 10-2024-0136080

(51) Int. Cl. G11C 29/12; G11C 29/18

(52) U.S. Cl. CPC G11C 29/12005; G11C 29/1201; G11C 29/18; G11C 2029/1802

(57) ABSTRACT

A memory device includes a memory block with a plurality of cell strings connected to a bit line, each of the cell strings including a plurality of selection transistors connected to a plurality of selection lines and a plurality of memory cells connected to a plurality of word lines, a row decoding circuit that applies at least two different test voltages to the plurality of selection lines and applies pass voltages to the word lines, in a test operation, and a control circuit including a sensing node. In the test operation, the control circuit connects the bit line and the sensing node during a first time after the test voltages are applied, to sense whether a voltage of the sensing node is changed to a first reference voltage or lower, and terminates the test operation or performs a subsequent operation following the test operation, based on the sensing.

### CROSS-REFERENCE TO RELATED APPLICATION(S)

This application claims priority under 35 U.S.C. § 119 to Korean Patent Application No. 10-2024-0136080 filed on Oct. 7, 2024, in the Korean Intellectual Property Office, the disclosures of which are incorporated by reference herein in their entireties.

### BACKGROUND

Implementations of the present disclosure described herein relate to a semiconductor memory, and more particularly, relate to a memory device and an operation method thereof.

A semiconductor memory is classified as a volatile memory, which loses data stored therein when a power is turned off, such as a static random access memory (SRAM) or a dynamic random access memory (DRAM) or a nonvolatile memory, which retains data stored therein even when a power is turned off, such as a flash memory, a phase-change RAM (PRAM), a magnetic RAM (MRAM), a resistive RAM (RRAM), or a ferroelectric RAM (FRAM).

The flash memory device is being widely used as a high-capacity storage medium. In general, the flash memory device stores data or reads the stored data by controlling levels of various lines (e.g., a string selection line, a word line, and a ground selection line) connected to a plurality of memory cells. When various lines are controlled individually in units of cell string, the reliability and performance of the flash memory device may be improved, but it is difficult to form lines individually due to the increase in complexity of the process of manufacturing the flash memory device.

### SUMMARY

Implementations of the present disclosure provide a memory device with improved reliability and improved reliability and an operation method thereof.

According to some implementations, a memory device includes a memory block that includes a plurality of cell strings connected to a bit line, each of the plurality of cell strings including a plurality of selection transistors connected to a plurality of selection lines and a plurality of memory cells connected to a plurality of word lines, a row decoding circuit that applies at least two different first test voltages to the plurality of selection lines and applies pass voltages to the word lines, in a test operation, and a control circuit including a sensing node. In the test operation, the control circuit connects the bit line and the sensing node during a first time after the at least two different first test voltages are applied, to sense whether a voltage of the sensing node is changed to a first reference voltage or lower, and terminates the test operation or performs a subsequent operation following the test operation, based on sensing whether the voltage of the sensing mode is changed to the first reference voltage or lower.

According to some implementations, an operation method of a memory device which includes a sensing node, a bit line, and a first cell string and a second cell string connected to the bit line, the first cell string including first selection transistors and first memory cells and the second cell string including second selection transistors and second memory cells includes precharging the bit line and the sensing node, applying at least two different test voltages to the first selection transistors and the second selection transistors, applying pass voltages to the first memory cells and the second memory cells, connecting the sensing node and the bit line to sense whether a voltage of the sensing node is changed to a first reference voltage or lower during a first time, and performing a subsequent operation for the memory device, based on the sensing.

According to some implementations, a storage device includes a nonvolatile memory device that includes a plurality of memory blocks and a control circuit controlling the plurality of memory blocks, and a memory controller that controls the nonvolatile memory device. Each of the plurality of memory blocks includes a plurality of cell strings. Each of the plurality of cell strings includes a plurality of selection transistors connected to a plurality of selection lines and a plurality of memory cells connected to a plurality of word lines. The control circuit applies at least two different test voltages to selection lines connected to a first cell string included in a first memory block among the plurality of memory blocks and applies pass voltages to word lines connected to the first cell string to check whether a channel path of the first cell string is formed.

### BRIEF DESCRIPTION OF THE FIGURES

The above and other objects and features of the present disclosure will become apparent by describing in detail implementations thereof with reference to the accompanying drawings.

FIG. 1 is a diagram illustrating a memory device according to some implementations of the present disclosure.

FIG. 2 is a circuit diagram illustrating a first memory block included in a memory cell array of FIG. 1.

FIGS. 3 and 4 are diagrams for describing a method of controlling a first memory block of FIG. 2.

FIG. 5 is a diagram for describing a method for performing a first test operation in a memory device, according to some implementations of the present disclosure.

FIG. 6 is a diagram illustrating test voltages according to threshold voltage distributions of selection transistors.

FIG. 7 is a diagram for describing a method for performing a second test operation in a memory device, according to some implementations of the present disclosure.

FIG. 8 is a diagram illustrating a configuration of a page buffer circuit, according to some implementations of the present disclosure.

FIG. 9 is a diagram illustrating a voltage change of a sensing node during an operation of a page buffer circuit.

FIG. 10 is a diagram for comparing driving currents, reference sensing currents, and cutoff currents of selection transistors, according to some implementations of the present disclosure.

FIG. 11 is a diagram for describing a method in which a page buffer circuit adjusts a reference sensing current.

FIG. 12 is a diagram illustrating a change in a reference sensing current according to a change in a reference sensing time.

FIG. 13 is a flowchart for describing a test operation, according to some implementations of the present disclosure.

FIG. 14 is a diagram illustrating a storage device, according to some implementations of the present disclosure.

### DETAILED DESCRIPTION

Below, implementations of the present disclosure will be described in detail and clearly to such an extent that an ordinary one in the art easily carries out the present disclosure.

A method of electrically distinguishing cell strings by controlling levels of various lines (e.g., a string selection line, a word line, and a ground selection line) connected to a plurality of memory cells or selection transistors is provided, in which threshold voltages or threshold voltage distributions of the plurality of memory cells or selection transistors are checked.

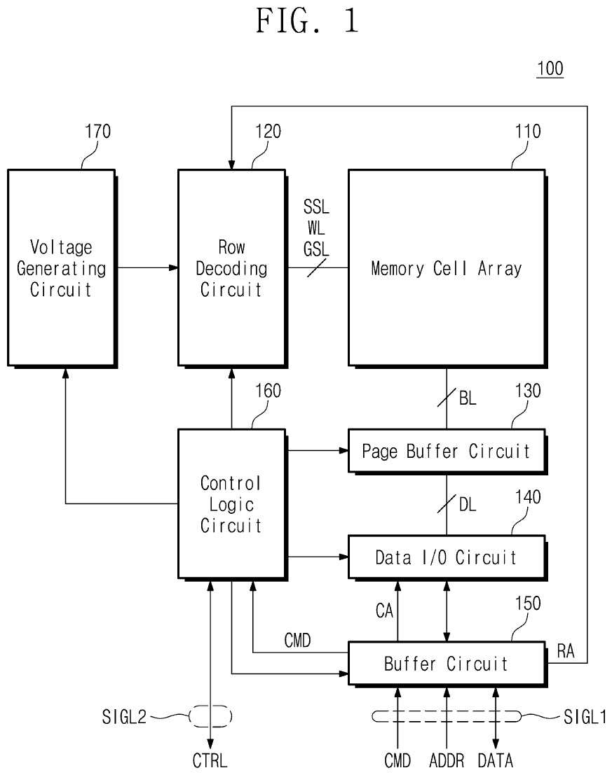

FIG. 1 is a diagram illustrating a memory device according to some implementations of the present disclosure. Referring to FIG. 1, a memory device 100 may include a memory cell array 110 and control circuits 120 to 170 controlling the memory cell array 110. For example, the memory device 100 may include the memory cell array 110, a row decoding circuit 120, a page buffer circuit 130, a data input/output circuit 140, a buffer circuit 150, a control logic circuit 160, and a voltage generating circuit 170. In some implementations, the memory device 100 may include a NAND flash memory device, but the present disclosure is not limited thereto.

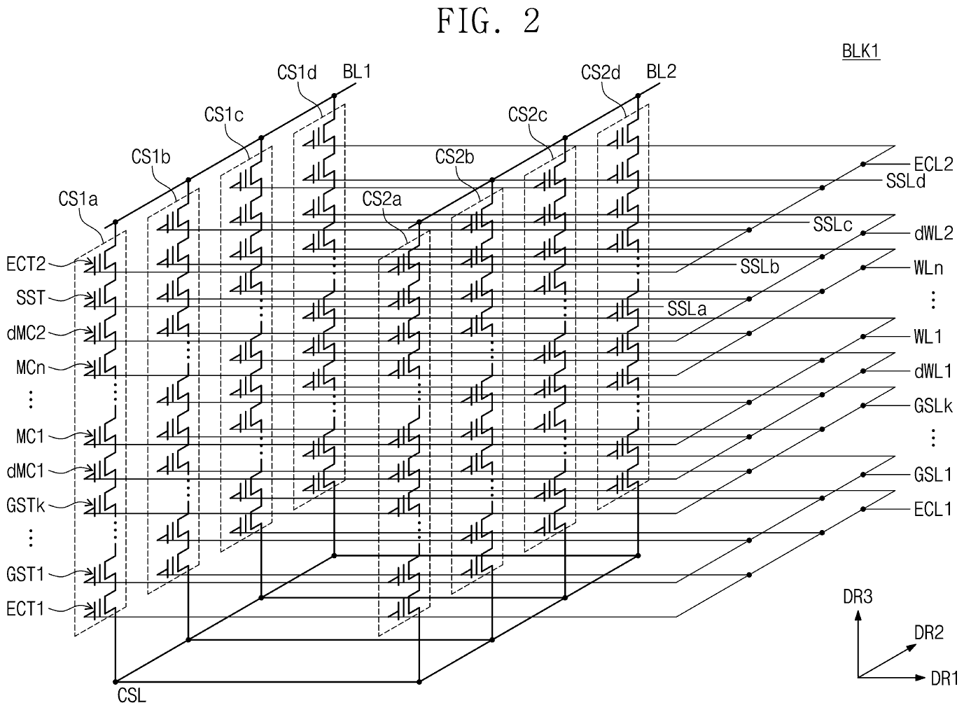

The memory cell array 110 may include a plurality of memory blocks. Each of the plurality of memory blocks may include a plurality of cell strings. Each of the plurality of cell strings may include a plurality of cell transistors stacked in a direction perpendicular to a substrate. The plurality of cell transistors may be connected in series between bit lines BL and a common source line. The plurality of cell transistors may be connected to string selection lines SSL, word lines WL, and ground selection lines GSL. The plurality of memory blocks will be described in detail with reference to FIG. 2.

The row decoding circuit 120 may be connected to the memory cell array 110 through the string selection lines SSL, the word lines WL, and the ground selection lines GSL. The row decoding circuit 120 may operate under control of the control logic circuit 160. For example, under control of the control logic circuit 160, the row decoding circuit 120 may decode a row address RA received from the buffer circuit 150; based on a decoding result, the row decoding circuit 120 may control or drive the string selection lines SSL, the word lines WL, and the ground selection lines GSL or may control voltages to be applied to the string selection lines SSL, the word lines WL, and the ground selection lines GSL.

The page buffer circuit 130 may be connected to the memory cell array 110 through the bit lines BL. The page buffer circuit 130 may be connected to the data input/output circuit 140 through a plurality of data lines DL. The page buffer circuit 130 may operate under control of the control logic circuit 160. For example, in the program operation of the memory device 100, the page buffer circuit 130 may store data to be programmed in the memory cell array 110 under control of the control logic circuit 160. In the read operation of the memory device 100, the page buffer circuit 130 may connect sensing nodes to the bit lines BL, may sense voltages of the sensing nodes, and may store the sensed voltages as read data.

The data input/output circuit 140 may be connected to the page buffer circuit 130 through the plurality of data lines DL. The data input/output circuit 140 may receive a column address CA from the buffer circuit 150. The data input/output circuit 140 may transmit the data read by the page buffer circuit 130 to the buffer circuit 150 depending on the column address CA. The data input/output circuit 140 may transmit the data received from the buffer circuit 150 to the page buffer circuit 130, based on the column address CA.

The buffer circuit 150 may receive a command CMD and an address ADDR from an external device (e.g., a controller) through first signal lines SIGL1 and may exchange data “DATA” with the external device (e.g., a controller) through the first signal lines SIGL1. In some implementations, the first signal lines SIGL1 may include data signal lines (e.g., DQ lines) and a data strobe signal line (e.g., a DQS line).

The buffer circuit 150 may operate under control of the control logic circuit 160. For example, the control logic circuit 160 may exchange a control signal CTRL with the external device (e.g., a controller) through second signal lines SIGL2. The control logic circuit 160 may control the buffer circuit 150 based on the control signals CTRL such that the buffer circuit 150 routes the command CMD, the address ADDR, and the data “DATA”. Under control of the control logic circuit 160, the buffer circuit 150 may classify signals received through the first signal lines SIGL1 as the command CMD or the address ADDR. The buffer circuit 150 may transfer the command CMD to the control logic circuit 160. The buffer circuit 150 may transfer the row address RA of the address ADDR to the row decoding circuit 120 and may transfer the column address CA of the address ADDR to the data input/output circuit 140. The buffer circuit 150 may exchange the data “DATA” with the data input/output circuit 140.

The control logic circuit 160 may decode the command CMD received from the buffer circuit 150 and may control the memory device 100 or various components of the memory device 100 based on a decoding result.

Under control of the control logic circuit 160, the voltage generating circuit 170 may generate various operating voltages VOP which are used in the memory device 100. In some implementations, the operating voltages VOP may include various voltages such as program voltages, pass voltages, selection read voltages, non-selection read voltages, erase voltages, and verify voltages. Below, various voltages which are used to describe implementations of the present disclosure may be included in the operating voltages VOP generated by the voltage generating circuit 170.

FIG. 2 is a circuit diagram illustrating a first memory block included in a memory cell array of FIG. 1. A structure of a first memory block BLK1 will be described with reference to FIG. 2, but the present disclosure is not limited thereto. For example, the memory cell array 110 may include a plurality of memory blocks, each of which is similar in structure to the first memory block BLK1 of FIG. 2.

In some implementations, the first memory block BLK1 to be described with reference to FIG. 2 may correspond to a physical erase unit of the memory device 100. However, the present disclosure is not limited thereto. For example, the memory device 100 may perform the erase operation in units of page, word line, sub-block, or plane.

In some implementations, the first memory block BLK1 to be described with reference to FIG. 2 is provided only as an example. The number of cell strings may increase or decrease, and the number of rows of cell strings and the number of columns of cell strings may increase or decrease depending on the number of cell strings. Also, the number of cell transistors GST, GST, MC, dMC, and SST of the first memory block BLK1 may increase or decrease, and the height of the first memory block BLK1 may increase or decrease depending on the number of cell transistors. In addition, the number of lines GSL, WL, dWL, and SSL connected to the cell transistors may increase or decrease depending on the number of cell transistors.

The first memory block BLK1 may include a plurality of cell strings CS1a to CS2d connected to bit lines BL1 and BL2, and each of the plurality of cell strings CS1a to CS2d may include a plurality of selection transistors SST and GST1 to GSTk connected to a plurality of selection lines SSLa to SSLd and GSL1 to GSLk and a plurality of memory cells MC1 to MCn connected to a plurality of word lines WL1 to WLn.

Referring to FIGS. 1 and 2, the first memory block BLK1 may include the plurality of cell strings CS1a, CS1b, CS1c, CS1d, CS2a, CS2b, CS2c, and CS2d. The plurality of cell strings CS1a to CS2d may be disposed along a first direction DR1 and a second direction DR2 to form rows and columns.

The plurality of cell strings CS1a to CS2d may be connected to the bit lines BL1 and BL2. For example, each of the bit lines BL1 and BL2 may extend along the second direction DR2. The cell strings CS1a, CS1b, CS1c, and CS1d located at the same column, that is, the first column from among the plurality of cell strings CS1a to CS2d may be connected to the first bit line BL1, and the cell strings CS2a, CS2b, CS2c, and CS2d located at the same column, that is, the second column from among the plurality of cell strings CS1a to CS2d may be connected to the second bit line BL2.

The 1a-th cell string CS1a may include a plurality of cell transistors connected in series between the first bit line BL1 and a common source line CSL. The plurality of cell transistors of the 1a-th cell string CS1a located at the first column and first row may include a first erase control transistor ECT1, the plurality of ground selection transistors GST1 to GSTk, dummy memory cells dMC1 and dMC2, the plurality of memory cells MC1 to MCn, the string selection transistor SST, and a second erase control transistor ECT2. In some implementations, each of the plurality of cell transistors may be implemented with a charge trap flash (CTF) memory cell.

The plurality of cell transistors of the 1a-th cell string CS1a may be connected in series and may be stacked in a third direction DR3 (or a height direction) which is a direction perpendicular to a plane defined by the first direction DR1 and the second direction DR2 or a substrate. For example, the plurality of memory cells MC1 to MCn may be connected in series and may be stacked in the third direction DR3 being a direction perpendicular to the substrate. The string selection transistor SST may be provided between the plurality of memory cells MC1 to MCn and the first bit line BL1. The plurality of ground selection transistors GST1 to GSTk may be connected in series and may be stacked in the third direction DR3 (or a height direction) being a direction perpendicular to the substrate. The plurality of ground selection transistors GST1 to GSTk connected in series may be provided between the plurality of serially-connected memory cells MC1 to MCn and the common source line CSL.

In some implementations, the first dummy memory cell dMC1 may be provided between the plurality of memory cells MC1 to MCn and the plurality of ground selection transistors GST1 to GSTk. In some implementations, the second dummy memory cell dMC2 may be provided between the plurality of memory cells MC1 to MCn and the string selection transistor SST.

In some implementations, the first erase control transistor ECT1 may be provided between the plurality of ground selection transistors GST1 to GSTk and the common source line CSL. The second erase control transistor ECT2 may be provided between the string selection transistor SST and the first bit line BL1. The first and second erase control transistors ECT1 and ECT2 may be used to charge the channel of the 1a-th cell string CS1a with an erase voltage or to erase the first memory block BLK1, based on a gate induced drain leakage (GIDL) phenomenon.

For convenience of description, the structure of the 1a-th cell string CS1a is described, but the present disclosure is not limited thereto. For example, each of the remaining cell strings CS1b to CS1d and CS2a to CS2d may be similar in structure to the 1a-th cell string CS1a.

The first erase control transistors ECT1 of the plurality of cell strings CS1a to CS2d may be connected in common to a first erase control line ECL1. The second erase control transistors ECT2 of the plurality of cell strings CS1a to CS2d may be connected in common to a second erase control line ECL2.

Memory cells located at the same height from the substrate from among the plurality of memory cells MC1 to MCn may be connected in common to the same word line, and memory cells located at any other height from among the plurality of memory cells MC1 to MCn may be connected in common to any other word line. For example, the first memory cells MC1 of the plurality of cell strings CS1a to CS2d may be located at the same height from the substrate and may be connected in common to a first word line WL1. The n-th memory cells MCn of the plurality of cell strings CS1a to CS2d may be located at the same height from the substrate and may be connected in common to an n-th word line WLn.

In some implementations, the first dummy memory cells dMC1 of the plurality of cell strings CS1a to CS2d may be located at the same height from the substrate and may be connected in common to a first dummy word line dWL1. The second dummy memory cells dMC2 of the plurality of cell strings CS1a to CS2d may be located at the same height from the substrate and may be connected in common to a second dummy word line dWL2.

The string selection transistors SST of the plurality of cell strings CS1a to CS2d may be connected to the plurality of string selection lines SSLa to SSLd. For example, string selection transistors located at the same row may be connected to the same string selection line, and string selection transistors located at any other row may be connected to any other string selection line. In detail, the string selection transistors SST of the cell strings CS1a and CS2a located at the first row may be connected to the a-th string selection line SSLa; the string selection transistors SST of the cell strings CS1b and CS2b located at the second row may be connected to the b-th string selection line SSLb; the string selection transistors SST of the cell strings CS1c and CS2c located at the third row may be connected to the c-th string selection line SSLc; and, the string selection transistors SST of the cell strings CS1d and CS2d located at the fourth row may be connected to the d-th string selection line SSLd.

For brevity of drawing and for convenience of description, the description will be given as each of the plurality of cell strings CS1a to CS2d includes one string selection transistor SST, but the present disclosure is not limited thereto. Each of the plurality of cell strings CS1a to CS2d may include a plurality of string selection transistors, and string selection transistors located at the same row from among string selection transistors located at the same height from the substrate may be connected to the same string selection line; in this case, string selection transistors located at any other row may be connected to any other string selection line.

Ground selection transistors located at the same height from the substrate may be connected to the same ground selection line. For example, the first ground selection transistors GST1 of the plurality of cell strings CS1a to CS2d may be located at the same height from the substrate and may be connected in common to a first ground selection line GSL1. The k-th ground selection transistors GSTk of the plurality of cell strings CS1a to CS2d may be located at the same height from the substrate and may be connected in common to a k-th ground selection line GSLk.

As illustrated in FIG. 2, the plurality of cell strings CS1a to CS2d may be connected in common to the ground selection lines GSL1 to GSLk or may share the ground selection lines GSL1 to GSLk. In this case, as the plurality of cell strings CS1a to CS2d are controlled by the same ground selection line, a ground selection transistor of an unselected cell string may be turned on during the read operation, the verify operation, or the channel recovery operation, thereby causing issues such as the reduction of reliability, the reduction of performance, and the increase in power consumption.

To solve the above issues, the ground selection transistors GST1 to GSTk of the plurality of cell strings CS1a to CS2d may be connected to a ground selection line in units of rows such that the plurality of cell strings CS1a to CS2d are controlled individually or in units of rows. In this case, a ground selection transistor of an unselected cell string may be turned off during the read operation, the verify operation, or the channel recovery operation, and thus, issues such as the reduction of reliability, the reduction of performance, and the increase in power consumption may be solved.

However, the physical limitation of the first memory block BLK1 may make it difficult (or impossible) to implement a structure in which the ground selection transistors GST1 to GSTk of the plurality of cell strings CS1a to CS2d are connected to a ground selection line in units of rows.

In this case, the plurality of cell strings CS1a to CS2d may be individually controlled by individually setting a threshold voltage of each of the ground selection transistors GST1 to GSTk of the plurality of cell strings CS1a to CS2d and controlling voltages of the plurality of ground selection lines GSL1 to GSLk.

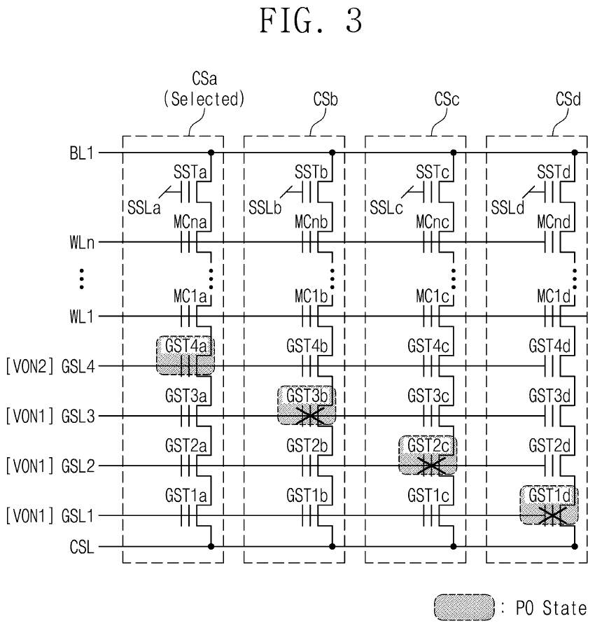

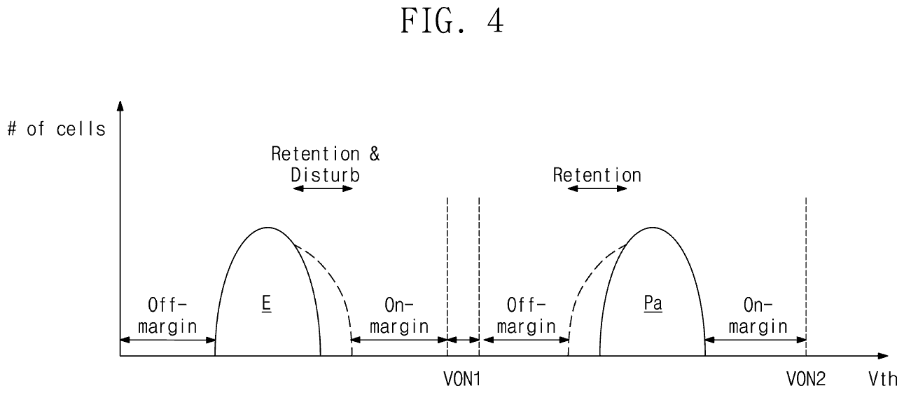

FIGS. 3 and 4 are diagrams for describing a method of controlling a first memory block of FIG. 2. Below, for convenience of description, implementations of the present disclosure will be described based on the plurality of cell strings CSa, CSb, CSc, and CSd connected to the first bit line BL1. Also, some (e.g., dummy memory cells and erase control transistors) of cell transistors included in each of the plurality of cell strings CSa, CSb, CSc, and CSd are omitted. However, the present disclosure is not limited thereto.

Below, for brevity of drawing and for convenience of description, some ground selection lines GSL and some ground selection transistors GST are illustrated in a drawing, but the present disclosure is not limited thereto. For example, in the following drawings, ground selection transistors or dummy ground selection transistors are illustrated as being directly connected to the common source line CSL, but additional ground selection transistors may further exist between the ground selection transistors or the dummy ground selection transistors and the common source line CSL.

Referring to FIGS. 1 to 4, the first memory block BLK1 may include the a-th to d-th cell strings CSa to CSd. Each of the a-th to d-th cell strings CSa to CSd may be connected between the first bit line BL1 and the common source line CSL. The a-th cell string CSa may include a plurality of ground selection transistors GST1a to GST4a, a plurality of memory cells MC1a to MCna, and an a-th string selection transistor SSTa. The b-th cell string CSb may include a plurality of ground selection transistors GST1b to GST4b, a plurality of memory cells MC1b to MCnb, and a b-th string selection transistor SSTb. The c-th cell string CSc may include a plurality of ground selection transistors GST1c to GST4c, a plurality of memory cells MC1c to MCnc, and a c-th string selection transistor SSTc. The d-th cell string CSd may include a plurality of ground selection transistors GST1d to GST4d, a plurality of memory cells MC1d to MCnd, and a d-th string selection transistor SSTd.

The string selection transistors SSTa of the a-th cell string CSa may be connected to the a-th string selection line SSLa; the string selection transistors SSTb of the b-th cell string CSb may be connected to the b-th string selection line SSLb; the string selection transistors SSTc of the c-th cell string CSc may be connected to the c-th string selection line SSLc; and, the string selection transistors SSTd of the d-th cell string CSd may be connected to the d-th string selection line SSLd.

The ground selection transistors GST1a to GST4a, GST1b to GST4b, GST1c to GST4c, and GST1d to GST4d and the memory cells MC1a to MCna, MC1b to MCnb, MC1c to MCnc, and MC1d to MCnd of a-th to d-th cell strings CSa to CSd may be connected to the plurality of ground selection lines GSL1 to GSL4 and the plurality of word lines WL1 to WLn. For example, the first memory cells MC1a, MC1b, MC1c, and MC1d of the a-th to d-th cell strings CSa to CSd may be connected to the first word line WL1, and the n-th memory cells MCna, MCnb, MCnc, and MCnd of the a-th to d-th cell strings CSa to CSd may be connected to the n-th word line WLn.

The ground selection transistors GST1a, GST1b, GST1c, and GST1d of the a-th to d-th cell strings CSa to CSd may be connected to the first ground selection line GSL1; the ground selection transistors GST2a, GST2b, GST2c, and GST2d of the a-th to d-th cell strings CSa to CSd may be connected to the second ground selection line GSL2; the ground selection transistors GST3a, GST3b, GST3c, and GST3d of the a-th to d-th cell strings CSa to CSd may be connected to the third ground selection line GSL3; and, the ground selection transistors GST4a, GST4b, GST4c, and GST4d of the a-th to d-th cell strings CSa to CSd may be connected to the fourth ground selection line GSL4.

In some implementations, while the memory device 100 operates, one of the plurality of cell strings CSa to CSd may be selected, and the remaining cell strings may not be selected. In this case, a threshold voltage of each of the plurality of ground selection transistors GST1a to GST4d may be set such that the remaining unselected cell strings among the plurality of cell strings CSa to CSd other than the selected cell string are not electrically connected to the common source line CSL. For example, as a selection voltage is applied to at least one of the first to fourth ground selection lines GSL1 to GSL4, at least one of the ground selection transistors connected to the at least one ground selection line may be turned on, and the others thereof may be turned off.

For example, as illustrated in FIG. 4, a threshold voltage or a threshold voltage distribution of an a-th program state Pa may be higher than a threshold voltage or a threshold voltage distribution of an erase state “E”. In this case, a ground selection transistor having the a-th program state Pa may be turned off by a first on-voltage VON1 and may be turned on by a second on-voltage VON2. In some implementations, the threshold voltage distribution of the erase state “E” may be different from the threshold voltage distribution of the a-th program state Pa. In some implementations, the threshold voltage distribution of the erase state “E” may be lower than the threshold voltage distribution of the a-th program state Pa. For example, threshold voltages of ground selection transistors corresponding to the erase state “E” may be lower than threshold voltages of ground selection transistors corresponding to the a-th program state Pa. In some implementations, the threshold voltages of the ground selection transistors corresponding to the erase state “E” may be different from threshold voltages of memory cells MC corresponding to the erase state “E”.

The threshold voltages of 4a-th, 3b-th, 2c-th, and 1d-th ground selection transistors GST4a, GST3b, GST2c, and GST1d among the plurality of ground selection transistors GST1a to GST4d may be set to the a-th program state Pa. In this case, as the first on-voltage VON1 or the second on-voltage VON2 is applied to each of the plurality of ground selection lines GSL1 to GSL4, the remaining unselected cell strings among the plurality of cell strings CSa to CSd other than the selected cell string may not be electrically connected to the common source line CSL.

For example, when the a-th cell string CSa is a selected cell string, the first on-voltage VON1 may be applied to the first to third ground selection lines GSL1 to GSL3, and the second on-voltage VON2 may be applied to the fourth ground selection line GSL4. As the first on-voltage VON1 is applied to the first ground selection line GSL1, the 1a-th, 1b-th, and 1c-th ground selection transistors GST1a, GST1b, and GST1c may be turned on, and the 1d-th ground selection transistor GST1d may be turned off. As the first on-voltage VON1 is applied to the second ground selection line GSL2, the 2a-th, 2b-th, and 2d-th ground selection transistors GST2a, GST2b, and GST2d may be turned on, and the 2c-th ground selection transistor GST2c may be turned off. As the first on-voltage VON1 is applied to the third ground selection line GSL3, the 3a-th, 3c-th, and 3d-th ground selection transistors GST3a, GST3c, and GST3d may be turned on, and the 3b-th ground selection transistor GST3b may be turned off. As the second on-voltage VON2 is applied to the fourth ground selection line GSL4, the ground selection transistors GST4a, GST4b, GST4c, and GST4d connected to the fourth ground selection line GSL4 may be turned on.

That is, according to the above bias condition associated with the ground selection lines GSL1 to GSL4, because all the ground selection transistors GST1a to GST4a of the a-th cell string CSa being the selected cell string are turned on, the a-th cell string CSa may be electrically connected to the common source line CSL. In contrast, because the 3b-th, 2c-th, and 1d-th ground selection transistors GST3b, GST2c, and GST1d are turned off, the b-th, c-th, and d-th cell strings CSb, CSc, and CSd being the unselected cell strings may be electrically separated from the common source line CSL. Accordingly, issues, which may occur during the operation of the memory device 100, such as the reduction of reliability, the reduction of performance, and the increase in power consumption may be prevented.

In some implementations, the program operation associated with the ground selection lines GSL1 to GSL4 may be performed to set the ground selection transistors GST4a, GST3b, GST2c, and GST1d to threshold voltages of the a-th program state Pa. For example, the threshold voltage of the 4a-th ground selection transistor GST4a may be set to the a-th program state Pa by applying the program voltage to the fourth ground selection line GSL4 and applying the pass voltage to the remaining lines (e.g., GSL1 to GSL3 and WL1 to WLn). The threshold voltage of the 3b-th ground selection transistor GST3b may be set to the a-th program state Pa by applying the program voltage to the third ground selection line GSL3 and applying the pass voltage to the remaining lines (e.g., GSL1, GSL2, GSL4, and WL1 to WLn). The threshold voltage of the 2c-th ground selection transistor GST2c may be set to the a-th program state Pa by applying the program voltage to the second ground selection line GSL2 and applying the pass voltage to the remaining lines (e.g., GSL1, GSL3, GSL4, and WL1 to WLn). The threshold voltage of the 1d-th ground selection transistor GST1d may be set to the a-th program state Pa by applying the program voltage to the first ground selection line GSL1 and applying the pass voltage to the remaining lines (e.g., GSL2, GSL3, GSL4, and WL1 to WLn).

In some implementations, the threshold voltages of the ground selection transistors GST1a to GST4d may be changed due to various factors. For example, as the memory device 100 operates, the threshold voltages of the ground selection transistors GST1a to GST4d may decrease due to a retention characteristic of the ground selection transistors GST1a to GST4d. Alternatively, the threshold voltages of the ground selection transistors GST1a to GST4d may increase due to the retention characteristic of the ground selection transistors GST1a to GST4d. Alternatively, as the memory device 100 operates, the read disturb may occur in the ground selection transistors GST1a to GST4d, thereby causing the increase in the threshold voltages of the ground selection transistors GST1a to GST4d. Alternatively, as the memory device 100 operates, a hot electron injection phenomenon may occur in the ground selection transistors GST1a to GST4d, thereby causing the increase in the threshold voltages of the ground selection transistors GST1a to GST4d.

As described above, as the threshold voltages of the ground selection transistors GST1a to GST4d are changed, the memory device 100 may not operate normally, thereby causing the reduction of performance and the reduction of reliability in the memory device 100. That is, there may be a need to check threshold voltages of the selection transistors SSTa to SSTd and GST1a to GST4d to check threshold voltage distributions.

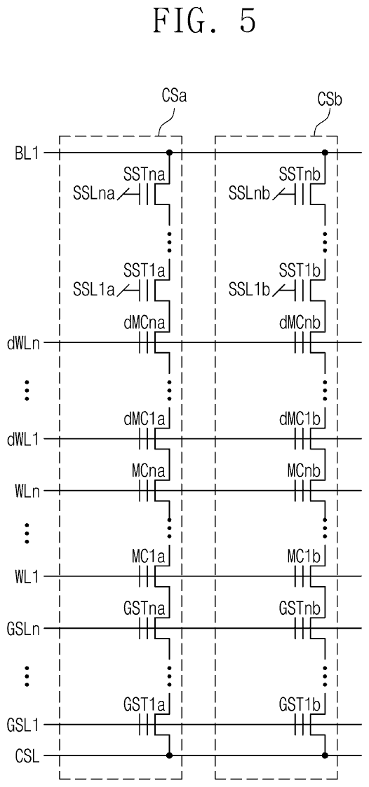

FIG. 5 is a diagram for describing a method for performing a first test operation in a memory device, according to some implementations of the present disclosure.

Referring to FIGS. 1, 2, and 5, in some implementations, for convenience of description and for brevity of drawing, implementations of the present disclosure will be described based on the a-th cell string CSa and the b-th cell string CSb connected to the first bit line BL1. Also, some (e.g., an erase control transistor) of cell transistors included in each of the a-th cell string CSa and the b-th cell string CSb are omitted. However, the present disclosure is not limited thereto. Also, the plurality of dummy memory cells dMC1a to dMCna may not be necessarily provided only between the first bit line BL1 and the plurality of word lines WL1 to WLn. For example, the plurality of dummy memory cells dMC1a to dMCna may be provided between the plurality of word lines WL1 to WLn and the plurality of ground selection lines GSL1 to GSL4.

Referring to FIG. 5, each of the a-th cell string CSa and the b-th cell string CSb may be connected between the first bit line BL1 and the common source line CSL. The a-th cell string CSa may include a plurality of ground selection transistors GST1a to GST4a, a plurality of memory cells MC1a to MCna, a plurality of dummy memory cells dMC1a to dMCna, and a plurality of string selection transistors SST1a to SSTna. The b-th cell string CSb may include a plurality of ground selection transistors GST1b to GST4b, a plurality of memory cells MC1b to MCnb, a plurality of dummy memory cells dMC1b to dMCnb, and a plurality of string selection transistors SST1b to SSTnb.

The string selection transistors SST1a to SSTna and SST1b to SSTnb, the dummy memory cells dMC1a to dMCna and dMC1b to dMCnb, the memory cells MC1a to MCna and MC1b to MCnb, and the ground selection transistors GST1a to GST4a and GST1b to GST4b of the a-th cell string CSa and the b-th cell string CSb may be connected to a plurality of string selection lines SSL1a to SSLna and SSL1b to SSLnb, a plurality of dummy word lines dWL1 to dWLn, a plurality of word lines WL1 to WLn, and a plurality of ground selection lines GSL1 to GSLn. For example, the first ground selection transistors GST1a and GST1b of the a-th cell string CSa and the b-th cell string CSb may be connected to the first ground selection line GSL1. For example, the first string selection transistor SST1a of the a-th cell string CSa may be connected to the 1a-th string selection line SSL1a, and the n-th string selection transistor SSTnb of the b-th cell string CSb may be connected to the nb-th string selection line SSLnb.

The string selection transistors SST1a to SSTna and SST1b to SSTnb, the dummy memory cells dMC1a to dMCna and dMC1b to dMCnb, and the ground selection transistors GST1a to GST4a and GST1b to GST4b of the a-th cell string CSa and the b-th cell string CSb may have at least two different threshold voltages or at least two different threshold voltage distributions.

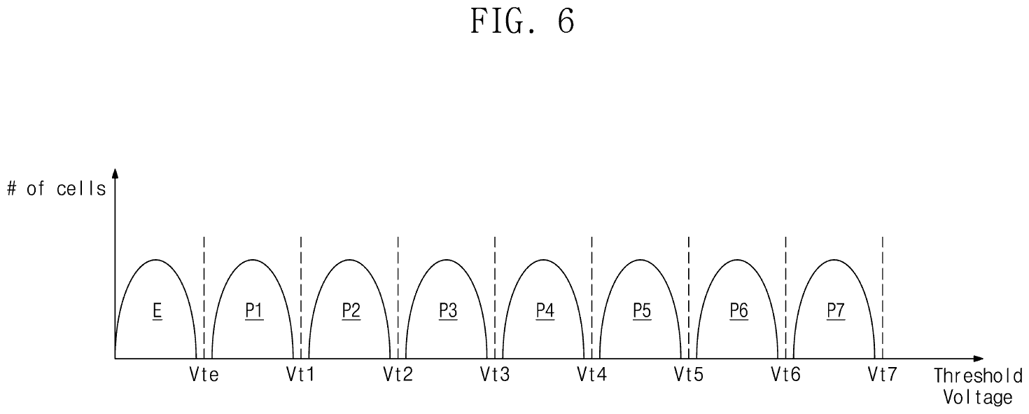

FIG. 6 is a diagram illustrating test voltages according to threshold voltage distributions of selection transistors.

Referring to FIGS. 5 and 6 together, a threshold voltage of each of the selection transistors SST1a to SSTna, SST1b to SSTnb, GST1a to GSTna, and GST1b to GSTnb and the dummy memory cells dMC1a to dMCna and dMC1b to dMCnb of the a-th cell string CSa and the b-th cell string CSb may be set to one of the erase state “E” and a first program state P1 to a seventh program state P7.

For example, as illustrated in FIG. 6, the threshold voltage or threshold voltage distribution of the first program state P1 may be higher than the threshold voltage or threshold voltage distribution of the erase state “E”. In this case, selection transistors or cells having the first program state P1 may be turned off by an e-th test voltage Vte and may be turned on by a first test voltage Vt1. Likewise, the threshold voltage or threshold voltage distribution of the second program state P2 may be higher than the threshold voltage or threshold voltage distribution of the first program state P1. The threshold voltage or threshold voltage distribution of the third program state P3 may be higher than the threshold voltage or threshold voltage distribution of the second program state P2. The threshold voltage or threshold voltage distribution of the fourth program state P4 may be higher than the threshold voltage or threshold voltage distribution of the third program state P3. The threshold voltage or threshold voltage distribution of the fifth program state P5 may be higher than the threshold voltage or threshold voltage distribution of the fourth program state P4. The threshold voltage or threshold voltage distribution of the sixth program state P6 may be higher than the threshold voltage or threshold voltage distribution of the fifth program state P5. The threshold voltage or threshold voltage distribution of the seventh program state P7 may be higher than the threshold voltage or threshold voltage distribution of the sixth program state P6.

Referring to FIG. 1 together, in a first test operation, the row decoding circuit 120 may be configured to apply test voltages and pass voltages to the memory cell array 110. For example, the row decoding circuit 120 may apply at least two different test voltages to the plurality of selection lines SSL1a to SSLna, SSL1b to SSLnb, and GSL1 to GSLn and may apply pass voltages to the plurality of word lines WL1 to WLn.

For example, the first test operation may mean an operation of executing a first test mode. For example, the first test mode may mean an operation of checking the upper limit of threshold voltages or threshold voltage distributions of transistors or cells. For example, the first test mode may mean an operation of checking the upper limit of threshold voltages or threshold voltage distributions of the selection transistors SST1a to SSTna and GST1a to GSTna and the dummy memory cells dMC1a to dMCna of the a-th cell string CSa.

For example, the test voltages may be set depending on the threshold voltages or threshold voltage distributions of the selection transistors SST1a to SSTna and GST1a to GSTna and the dummy memory cells dMC1a to dMCna. Referring to FIG. 6, in association with a transistor or cell having a threshold voltage or threshold voltage distribution of the erase state “E”, the test voltage may be set to the e-th test voltage Vte. In association with a transistor or cell having a threshold voltage or threshold voltage distribution of the first program state P1, the test voltage may be set to the first test voltage Vt1. In association with a transistor or cell having a threshold voltage or threshold voltage distribution of the second program state P2, the test voltage may be set to the second test voltage Vt2. In association with a transistor or cell having a threshold voltage or threshold voltage distribution of the third program state P3, the test voltages may be set to the third test voltage Vt3. In association with a transistor or cell having a threshold voltage or threshold voltage distribution of the fourth program state P4, the test voltage may be set to the fourth test voltage Vt4. In association with a transistor or cell having a threshold voltage or threshold voltage distribution of the fifth program state P5, the test voltage may be set to the fifth test voltage Vt5. In association with a transistor or cell having a threshold voltage or threshold voltage distribution of the sixth program state P6, the test voltage may be set to the sixth test voltage Vt6. In association with a transistor or cell having a threshold voltage or threshold voltage distribution of the seventh program state P7, the test voltage may be set to the seventh test voltage Vt7.

For example, the selection transistors SST1a to SSTna and GST1a to GSTna and the dummy memory cells dMC1a to dMCna of the a-th cell string CSa may have at least two different threshold voltages or threshold voltage distributions. For example, the threshold voltage or threshold voltage distribution of the first ground selection transistor GST1a of the a-th cell string CSa may correspond to the seventh program state P7. The threshold voltage or threshold voltage distribution of the fifth ground selection transistor GST5a of the a-th cell string CSa may correspond to the second program state P2. The threshold voltage or threshold voltage distribution of the tenth ground selection transistor GST10a of the a-th cell string CSa may correspond to the third program state P3. In this case, the test voltage to be applied to the first ground selection transistor GST1a of the a-th cell string CSa may be the seventh test voltage Vt7, the test voltage to be applied to the fifth ground selection transistor GST5a of the a-th cell string CSa may be the second test voltage Vt2, and the test voltage to be applied to the tenth ground selection transistor GST10a of the a-th cell string CSa may be the third test voltage Vt3.

As described with reference to FIG. 3, the a-th cell string CSa and the b-th cell string CSb may respectively include ground selection transistors set to different threshold voltages from among ground selection transistors sharing the same ground selection line. For example, the threshold voltage or threshold voltage distribution of the tenth ground selection transistor GST10a of the a-th cell string CSa may correspond to the third program state P3. In this case, the threshold voltage or threshold voltage distribution of the tenth ground selection transistor GST10b of the b-th cell string CSb may correspond to the seventh program state P7. Accordingly, test voltages which are used when the test operation for the a-th cell string CSa is performed may be different from test voltages which are used when the test operation for the b-th cell string CSb is performed.

When the first test mode is performed, a shut-off voltage may be applied to at least one among the selection transistors SST1b to SSTnb and GST1b to GSTnb included in the b-th cell string CSb. For example, the shut-off voltage may mean a voltage for turning off a selection transistor. For example, the shut-off voltages may be applied to selection transistors through a plurality of selection lines. For example, when the shut-off voltages are applied, a channel path of the b-th cell string CSb may not be formed. For example, at least one of the selection transistors SST1b to SSTnb and GST1b to GST4b of the b-th cell string CSb may be turned off.

For example, in the first test operation, the row decoding circuit 120 may be configured to apply the test voltages to the plurality of selection transistors GST1a to GSTna and SST1a to SSTna and the plurality of dummy memory cells dMC1a to dMCna of the a-th cell string CSa. For example, the row decoding circuit 120 may be configured to apply the test voltages to the plurality of string selection lines SSL1a to SSLna, the plurality of ground selection lines GSL1 to GSLn, and the plurality of dummy word lines dWL1 to dWLn of the a-th cell string CSa. Also, the row decoding circuit 120 may be configured to apply the pass voltages to the plurality of word lines WL1 to WLn.

For example, in the first test operation, the row decoding circuit 120 may be configured to apply the shut-off voltages to at least one of the plurality of string selection transistors SST1b to SSTnb of the b-th cell string CSb. That is, the row decoding circuit 120 may be configured to apply the shut-off voltage to at least one of the plurality of string selection lines SSL1b to SSLnb of the b-th cell string CSb. For example, a transistor, to which the shut-off voltage is applied, from among the plurality of string selection transistors SST1b to SSTnb of the b-th cell string CSb may be turned off. In some implementations, a case may occur in which the a-th cell string CSa and the b-th cell string CSb share the plurality of ground selection lines GSL1 to GSLn and do not share the plurality of string selection lines SSL1a to SSLna and SSL1b to SSLnb. However, when the plurality of ground selection lines GSL1 to GSLn are not shared, the row decoding circuit 120 may be configured to block the channel path of the b-th cell string CSb through the ground selection transistors GST1b to GSTnb of the b-th cell string CSb.

After the test voltages are applied, during a given time, the control circuits 120 to 170 may connect the first bit line BL1 to the sensing node to detect whether a voltage of the sensing node is changed to a reference voltage or lower. For example, the page buffer circuit 130 may be configured to sense the voltage change of the sensing node in the page buffer circuit 130 through the connection with the first bit line BL1. For example, in the first test operation, the page buffer circuit 130 may connect the first bit line BL1 and the sensing node during a first time and may check whether the voltage of the sensing node is changed to a first reference voltage or lower, that is, may check whether the channel path of the a-th cell string CSa is formed. For example, when the voltage of the sensing node connected to the first bit line BL1 is changed to the first reference voltage or lower during the first time, the page buffer circuit 130 may check that the channel path of the a-th cell string CSa is formed. For example, when the voltage of the sensing node connected to the first bit line BL1 is not changed to the first reference voltage or lower during the first time, the page buffer circuit 130 may check that the channel path of the a-th cell string CSa is not formed.

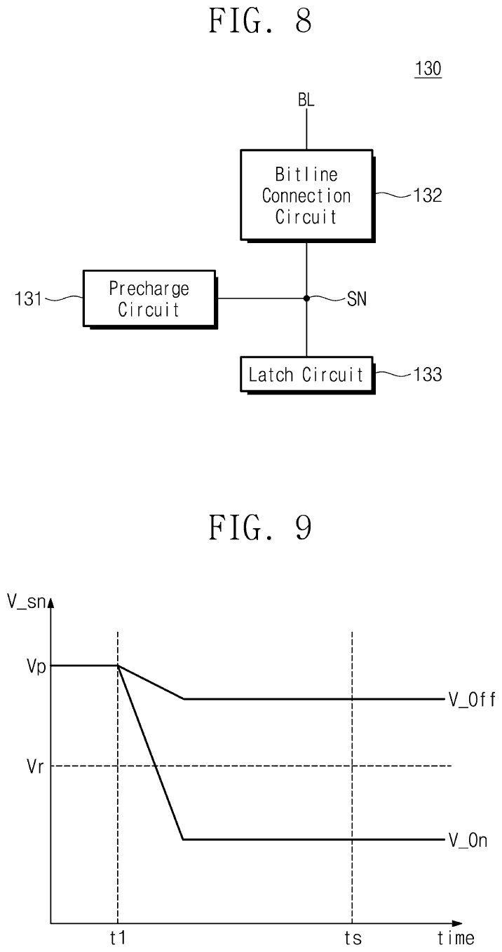

According to some implementations, in the first test operation, when the voltage of the sensing node connected to the first bit line BL1 is changed to the first reference voltage or lower during the first time, the page buffer circuit 130 may be configured to check that the upper limit of threshold voltages or threshold voltage distributions of the selection transistors SST1a to SSTna and GST1a to GSTna and the dummy memory cells dMC1a to dMCna of the a-th cell string CSa is normal. In this case, the page buffer circuit 130 may be configured to check that the upper limit of threshold voltages or threshold voltage distributions of the selection transistors SST1a to SSTna and GST1a to GSTna and the dummy memory cells dMC1a to dMCna are lower than the test voltages applied thereto. How the page buffer circuit 130 detects whether the voltage of the sensing node connected to the first bit line BL1 is changed to the reference voltage or lower during a given time will be described in detail with reference to FIGS. 8 to 12.

The control circuits 120 to 170 may be configured to terminate the first test operation or perform a subsequent operation following the first test operation, based on a result of sensing the voltage change of the sensing node connected to the first bit line BL1.

According to some implementations, in the first test operation, when the voltage of the sensing node connected to the first bit line BL1 is not changed to the first reference voltage or lower during the first time, the control circuits 120 to 170 may be configured to perform the test operation of each of the selection transistors SST1a to SSTna and GST1a to GST4a and the dummy memory cells dMC1a to dMCna of the a-th cell string CSa as the subsequent operation. For example, as the subsequent operation, the control circuits 120 to 170 may be configured to check the programmed threshold voltages or threshold voltage distributions of the selection transistors SST1a to SSTna and GST1a to GST4a and the dummy memory cells dMC1a to dMCna of the a-th cell string CSa.

According to some implementations, in the first test operation, when the voltage of the sensing node connected to the first bit line BL1 is changed to the first reference voltage or lower during the first time, the control circuits 120 to 170 may be configured to perform the read, verify, program, or erase operation for the memory cell array 110 as the subsequent operation. As another example, the control circuits 120 to 170 may be configured to terminate the first test operation as the subsequent operation. In this case, the control circuits 120 to 170 may be configured to output a result of the first test operation to the external device.

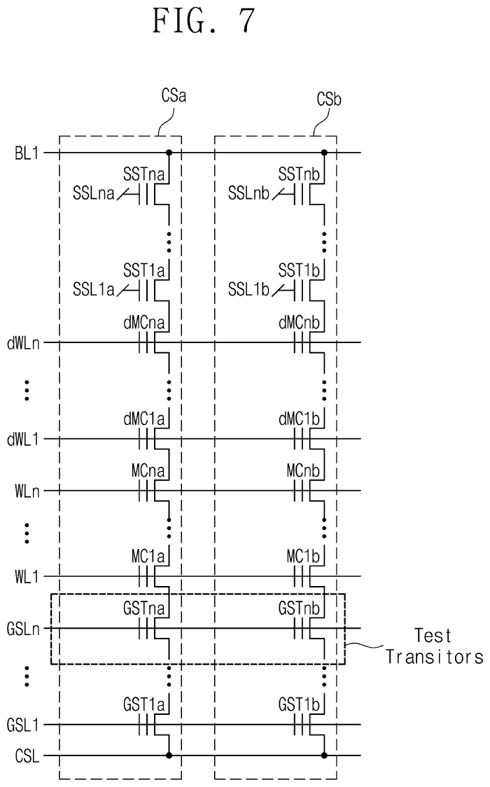

FIG. 7 is a diagram for describing a method for performing a second test operation in a memory device, according to some implementations of the present disclosure. Below, for convenience of description, additional description associated with the above components will be omitted to avoid redundancy.

Referring to FIG. 1 together, according to some implementations, a second test operation may mean performing a second test mode. For example, the second test mode may mean an operation of checking the lower limit of threshold voltages or threshold voltage distributions of transistors or cells. For example, the second test mode may mean an operation of checking the lower limit of threshold voltages or threshold voltage distributions of the string selection transistors SST1a to SSTna and SST1b to SSTnb, the dummy memory cells dMC1a to dMCna and dMC1b to dMCnb, the memory cells MC1a to MCna and MC1b to MCnb, and the ground selection transistors GST1a to GST4a and GST1b to GST4b of the a-th cell string CSa and the b-th cell string CSb.

According to some implementations, in the second test mode, the row decoding circuit 120 may be configured to perform the test operation for one transistor of each of the a-th cell string CSa and the b-th cell string CSb and to apply the pass voltages to the remaining transistors thereof.

For example, the row decoding circuit 120 may be configured to perform the test operation for one transistor of each of the a-th cell string CSa and the b-th cell string CSb. For example, the row decoding circuit 120 may be configured to perform the test operation for one transistor of the a-th cell string CSa and one transistor of the b-th cell string CSb. In this case, the transistors where the test operation will be performed may be transistors stacked at the same height. For example, the row decoding circuit 120 may be configured to perform the test operation for the n-th ground selection transistor GSTna of the a-th cell string CSa and the n-th ground selection transistor GSTnb of the b-th cell string CSb.

For example, the test operation may refer to an operation of checking the lower limit of threshold voltages or threshold voltage distributions of transistors. For example, the row decoding circuit 120 may be configured to apply the test voltage, based on the lowest threshold voltages or threshold voltage distributions of threshold voltages or threshold voltage distributions of the transistors where the test operation will be performed. For example, in the second test mode, the test voltage may be lower than the threshold voltages or threshold voltage distributions of the transistors. For example, the threshold voltage or threshold voltage distribution of the n-th ground selection transistor GSTna of the a-th cell string CSa may correspond to the second program state P2, and the threshold voltage or threshold voltage distribution of the n-th ground selection transistor GSTnb of the b-th cell string CSb may correspond to the third program state P3. In this case, the row decoding circuit 120 may be configured to apply the first test voltage Vt1 to the n-th ground selection line GSLn, based on the second program state P2.

For example, the row decoding circuit 120 may apply the pass voltages to the remaining transistors where the test operation is not performed.

For example, after the test voltages are applied, during a given time, the control circuits 120 to 170 may connect the first bit line BL1 to the sensing node to detect whether a voltage of the sensing node is changed to the reference voltage or lower. For example, the page buffer circuit 130 may be configured to sense the voltage change of the sensing node in the page buffer circuit 130 through the connection with the first bit line BL1. For example, in the second test operation, the page buffer circuit 130 may connect the first bit line BL1 and the sensing node during a given time and may check whether the voltage of the sensing node is changed to the reference voltage or lower, that is, may check whether the channel paths of the a-th cell string CSa and the b-th cell string CSb are formed.

For example, when the voltage of the sensing node connected to the first bit line BL1 is changed to the reference voltage or lower during the given time, the page buffer circuit 130 may check that the channel path is formed in the a-th cell string CSa or the b-th cell string CSb. For example, when the voltage of the sensing node connected to the first bit line BL1 is not changed to the reference voltage or lower during the given time, the page buffer circuit 130 may check that the channel path is not formed in the a-th cell string CSa and the b-th cell string CSb.

For example, when the channel path is not formed, the page buffer circuit 130 may check that the lower limit of the threshold voltages or threshold voltage distributions of the n-th ground selection transistor GSTna of the a-th cell string CSa and the n-th ground selection transistor GSTnb of the b-th cell string CSb is normal. In this case, the page buffer circuit 130 may be configured to check that the lower limit of the threshold voltages or threshold voltage distributions of the n-th ground selection transistor GSTna of the a-th cell string CSa and the n-th ground selection transistor GSTnb of the b-th cell string CSb is higher than or equal to the test voltages applied thereto. How the page buffer circuit 130 detects whether the voltage of the sensing node connected to the first bit line BL1 is changed to the reference voltage or lower during a given time will be described in detail with reference to FIGS. 8 to 12.

According to some implementations, the control circuits 120 to 170 may be configured to terminate the second test operation or perform a subsequent operation following the second test operation, based on a result of sensing the voltage change of the sensing node connected to the first bit line BL1. For example, the control circuits 120 to 170 may be configured to perform the test operation for transistors, which do not experience the test operation, from among the transistors of the a-th cell string CSa and the b-th cell string CSb. As another example, the control circuits 120 to 170 may be configured to perform the read, verify, program, or erase operation for the memory cell array 110 as the subsequent operation. As another example, the control circuits 120 to 170 may be configured to terminate the second test operation as the subsequent operation. In this case, the control circuits 120 to 170 may be configured to output a result of the second test operation to the external device.

FIG. 8 is a diagram illustrating a configuration of a page buffer circuit, according to some implementations of the present disclosure.

Referring to FIGS. 1, 5, 7, and 8, the page buffer circuit 130 may include a precharge circuit 131, a bit line connection circuit 132, a latch circuit 133, and a sensing node SN. For example, the precharge circuit 131, the bit line connection circuit 132, and the latch circuit 133 may be connected through the sensing node SN.

The precharge circuit 131 may be configured to precharge the bit line BL and the sensing node SN. For example, the precharge circuit 131 may apply a first precharge voltage to the bit line BL. For example, the precharge circuit 131 may set a node voltage of the sensing node SN to a second precharge voltage.

The bit line connection circuit 132 may be configured to connect the sensing node SN to the bit line BL. For example, the bit line connection circuit 132 may be configured to connect the sensing node SN to the bit line BL.

According to some implementations, the bit line connection circuit 132 may be configured to connect the sensing node SN to the bit line BL after the bit line BL and the sensing node SN are precharged. For example, after the precharge circuit 131 precharges the bit line BL and the sensing node SN with the first precharge voltage, the bit line connection circuit 132 may connect the bit line BL and the sensing node SN.

According to some implementations, the bit line connection circuit 132 may be configured to connect the bit line BL and the sensing node SN after voltages are applied to selection lines and word lines of cell strings connected to the bit line BL. For example, the bit line connection circuit 132 may be configured to connect the bit line BL and the sensing node SN after voltages are applied to the plurality of selection lines GSL1 to GSLn, SSL1a to SSLna, and SSL1b to SSLnb, the plurality of dummy word lines dWL1 to dWLn, and the plurality of word lines WL1 to WLn of the a-th cell string CSa and the b-th cell string CSb connected to the bit line BL. For example, the bit line connection circuit 132 may be configured to connect the bit line BL and the sensing node SN after the test voltages are applied to the plurality of selection lines GSL1 to GSLn, SSL1a to SSLna, and SSL1b to SSLnb and the plurality of dummy word lines dWL1 to dWLn of the a-th cell string CSa and the b-th cell string CSb and the pass voltages are applied to the plurality of word lines WL1 to WLn.

For example, after the precharge circuit 131 precharges the bit line BL and the sensing node SN with the first precharge voltage, the row decoding circuit 120 may be configured to apply the test voltages and the pass voltages to the plurality of selection lines GSL1 to GSLn, SSL1a to SSLna, and SSL1b to SSLnb, the plurality of dummy word lines dWL1 to dWLn, and the plurality of word lines WL1 to WLn of the a-th cell string CSa and the b-th cell string CSb and then connect the bit line BL and the sensing node SN.

The latch circuit 133 may be configured to compare a voltage of the sensing node SN and a reference voltage. For example, the latch circuit 133 may be configured to check a large-small relationship between the voltage of the sensing node SN and the reference voltage.

According to some implementations, the latch circuit 133 may be configured to compare the voltage of the sensing node SN and the reference voltage under control of the control logic circuit 160. For example, the control logic circuit 160 may be configured to allow the latch circuit 133 to perform voltage comparison after the bit line BL and the sensing node SN are precharged and the sensing node SN is connected to the bit line BL. For example, after the sensing node SN is connected to the bit line BL, the control logic circuit 160 may be configured to allow the latch circuit 133 to perform voltage comparison after a given time. For example, after the sensing node SN is connected to the bit line BL, the latch circuit 133 may be configured to compare the voltage of the sensing node SN and the reference voltage after the given time. For example, the control logic circuit 160 may be configured to control whether to allow the latch circuit 133 to perform voltage comparison after a certain time from a point in time when the sensing node SN is connected to the bit line BL.

For example, the control logic circuit 160 may be configured to allow the latch circuit 133 to perform voltage comparison after the bit line BL and the sensing node SN are precharged and the sensing node SN is connected to the bit line BL. For example, the control logic circuit 160 may allow the latch circuit 133 to perform a voltage comparison after a first time from a point in time when the sensing node SN is connected to the bit line BL. For example, the control logic circuit 160 may be configured to adjust the first time.

FIG. 9 is a diagram illustrating a voltage change of a sensing node during an operation of a page buffer circuit. Referring to FIG. 9, the x-axis represents a time, and the y-axis represents a voltage V_sn of the sensing node SN.

Referring to FIGS. 1, 5, 7, and 9, according to some implementations, an on-voltage V_On indicates a voltage of the sensing node SN when a channel path is formed in a cell string connected to the bit line BL, and an off-voltage V_Off indicates a voltage of the sensing node SN when a channel path is not formed in a cell string connected to the bit line BL.

According to some implementations, before a time point t1, the precharge circuit 131 may precharge the bit line BL. For example, a precharge voltage Vp may be applied to the bit line BL.

At the time point t1, the bit line connection circuit 132 may connect the sensing node SN to the bit line BL. As the sensing node SN is connected to the bit line BL, the voltage of the sensing node SN may decrease.

For example, the decrement of the on-voltage V_On, that is, the decrement of the voltage of the sensing node SN may be greater than the decrement of the off-voltage V_Off, that is, the decrement of the voltage of the sensing node SN.

At a time point ts, the latch circuit 133 may compare the voltage of the sensing node SN and a reference voltage Vr. For example, the time point ts may refer to a time point at which the control logic circuit 160 controls the latch circuit 133 to perform voltage comparison. For example, the control logic circuit 160 may be configured to adjust the time point ts.

For example, at the time point ts, the on-voltage V_On may be smaller than the reference voltage Vr. The control logic circuit 160 may check that a channel path is formed in the cell string connected to the bit line BL, based on the voltage of the sensing node SN being smaller than the reference voltage Vr at the time point ts.

For example, at the time point ts, the off-voltage V_off may be greater than the reference voltage Vr. The control logic circuit 160 may check that a channel path is not formed in the cell string connected to the bit line BL, based on the voltage of the sensing node SN being greater than the reference voltage Vr at the time point ts.

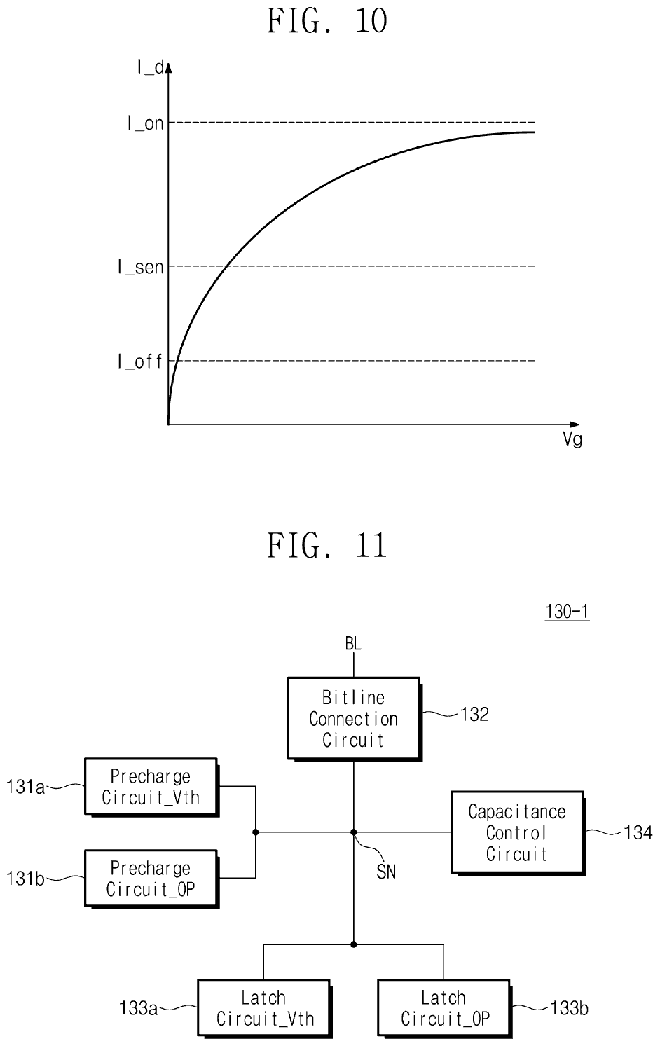

FIG. 10 is a diagram for comparing driving currents, reference sensing currents, and cutoff currents of selection transistors, according to some implementations of the present disclosure. Referring to FIG. 10, the x-axis represents a gate voltage, and the y-axis represents a drain current.

Referring to FIGS. 8, 9, and 10 together, according to some implementations, a driving current I_on may be larger than a reference sensing current I_sen. For example, the driving current I_on may indicate a drain current of a turned-on selection transistor when the memory device 100 performs the read, verify, program, or erase operation. For example, the driving current I_on may correspond to a saturation region of a drain current of a transistor.

For example, the reference sensing current I_sen may be a current which is used to detect whether memory cells are programmed. For example, the reference sensing current I_sen may be a current which is used when the read or verify operation for memory cells is performed. For example, the reference sensing current I_sen may mean a current which is used as a reference when the page buffer circuit 130 performs a voltage comparison. For example, the page buffer circuit 130 may compare a change in a sensing voltage with a reference voltage after a given time. In this case, the reference sensing current I_sen may mean a current when the sensing voltage decreases to the reference voltage after the given time. For example, the reference sensing current I_sen may be calculated through Equation 1 below.

$${I}_{sen} = \frac{{C}_{s} ( {V}_{p} - {V}_{r} )}{{t}_{s}} \qquad [ Equation 1 ]$$

In Equation 1, Isen represents the reference sensing current I_sen, Cs represents a capacitance of the sensing node SN of the page buffer circuit 130, Vp represents a precharge voltage, Vr represents a reference voltage, and ts represents a time at which voltage comparison is performed.

Referring to FIG. 1 together, according to some implementations, a cutoff current I_off may be smaller than the reference sensing current I_sen. For example, the cutoff current I_off may indicate a drain current of a turned-off selection transistor when the memory device 100 performs the read, verify, program, or erase operation.

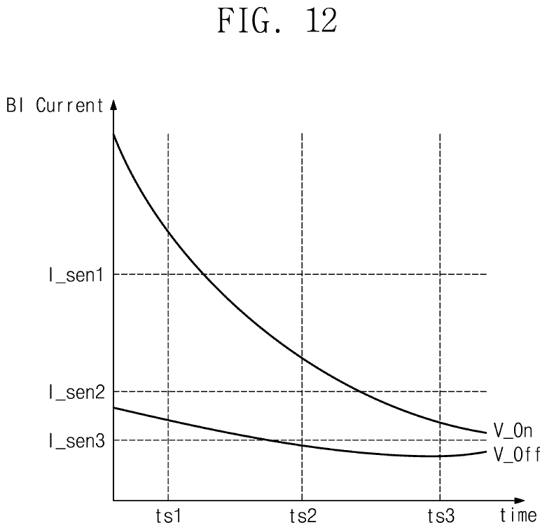

Referring to FIG. 1 together, according to some implementations, in the case of checking the upper limit of threshold voltages or threshold voltage distributions of selection transistors, the control circuits 120 to 170 may adjust the reference sensing current I_sen to be close to the driving current I_on. According to some implementations, in the case of checking the lower limit of threshold voltages or threshold voltage distributions of selection transistors, the control circuits 120 to 170 may adjust the reference sensing current I_sen to be close to the cutoff current I_off. How the control circuits 120 to 170 adjusts a reference sensing current will be described in detail with reference to FIGS. 11 and 12.

FIG. 11 is a diagram for describing a method in which a page buffer circuit adjusts a reference sensing current.

Referring to FIGS. 1, 5, 7, 8, and 11 together, a page buffer circuit 130-1 may include a test precharge circuit 131a, an operation precharge circuit 131b, the bit line connection circuit 132, a test latch circuit 133a, an operation latch circuit 133b, a capacitance control circuit 134, and the sensing node SN.

When the control circuits 120 to 170 perform the read, verify, program, or erase operation for the memory cell array 110, the operation precharge circuit 131b, the bit line connection circuit 132, the operation latch circuit 133b, and the sensing node SN may be used. For example, the operation precharge circuit 131b, the bit line connection circuit 132, the operation latch circuit 133b, and the sensing node SN may be configured to perform functions similar to those of the components of the page buffer circuit 130 of FIG. 8.

According to some implementations, when the first test operation or the second test operation is performed, the test precharge circuit 131a, the bit line connection circuit 132, the test latch circuit 133a, the capacitance control circuit 134, and the sensing node SN may be used.

According to some implementations, when there is performed the first test mode of checking the upper limit of threshold voltages or threshold voltage distributions of selection transistors or dummy memory cells, the page buffer circuit 130-1 may be configured to increase the reference sensing current. For example, when the first test mode is performed, the page buffer circuit 130-1 may be configured to use a reference sensing current which is higher than a reference sensing current used in the read, verify, program, or erase operation.

For example, when the first test mode is performed, the precharge voltage of the test precharge circuit 131a may be higher than the precharge voltage of the operation precharge circuit 131b. For example, the test precharge circuit 131a may be configured to apply the second precharge voltage to the sensing node SN. For example, the operation precharge circuit 131b may be configured to apply a third precharge voltage to the sensing node SN in the read or verify operation. For example, the second precharge voltage applied to the sensing node SN when the first test operation is performed may be higher than the third precharge voltage applied to the sensing node SN when the read or verify operation is performed.

For example, the reference voltage with which the test latch circuit 133a compares the voltage of the sensing node SN when the first test mode is performed may be lower than the reference voltage of the operation latch circuit 133b. For example, in the first test operation, the test latch circuit 133a may be configured to compare the voltage of the sensing node SN and the first reference voltage. For example, in the read or verify operation, the operation latch circuit 133b may be configured to compare the voltage of the sensing node SN and the second reference voltage. For example, the first reference voltage used in the first test operation may be lower than the second reference voltage used to sense the voltage change of the sensing node SN in the read or verify operation.

For example, when the first test mode is performed, the capacitance control circuit 134 may adjust the capacitance of the sensing node SN connected to the bit line BL. For example, the capacitance control circuit 134 may be configured to adjust the capacitance of the sensing node SN to a first capacitance in the first test operation. For example, in the read or verify operation, the capacitance control circuit 134 may be turned off. In this case, the capacitance of the sensing node SN may be a second capacitance. For example, the second capacitance may be smaller than the first capacitance. For example, the capacitance control circuit 134 may adjust the capacitance of the sensing node SN to the first capacitance in the first test operation and may adjust the capacitance of the sensing node SN to the second capacitance smaller than the first capacitance in the read or verify operation.

According to some implementations, when the first test mode is performed, the control logic circuit 160 may control the page buffer circuit 130-1 to use a sensing time shorter than a sensing time used to sense a voltage change of the sensing node SN in the read or verify operation. For example, the page buffer circuit 130-1 may be configured to sense the voltage change of the sensing node SN under control of the control logic circuit 160. For example, the control logic circuit 160 may control a reference time being a time during which the page buffer circuit 130-1 senses the voltage change. For example, in the first test operation, the time during which the page buffer circuit 130-1 senses the voltage change may be a first time. For example, in the read or verify operation, the time during which the page buffer circuit 130-1 senses the voltage change may be a second time. For example, under control of the control logic circuit 160, the first time may be set to be shorter than the second time. For example, the first time being a time which is used for the page buffer circuit 130-1 to sense the voltage change of the sensing node SN in the first test operation may be shorter than the second time being a time which is used for the page buffer circuit 130-1 to sense the voltage change of the sensing node SN in the read or verify operation.

According to some implementations, when the second test mode of checking the lower limit of threshold voltages or threshold voltage distributions of selection transistors or dummy memory cells is performed, the page buffer circuit 130-1 may be configured to decrease the reference sensing current. For example, when the second test mode is performed, the page buffer circuit 130-1 may be configured to use a reference sensing current which is lower than a reference sensing current used in the read, verify, program, or erase operation.

For example, when the second test mode is performed, the precharge voltage of the test precharge circuit 131a may be lower than the precharge voltage of the operation precharge circuit 131b. For example, the test precharge circuit 131a may be configured to apply a fourth precharge voltage to the sensing node SN. For example, the operation precharge circuit 131b may be configured to apply the third precharge voltage to the sensing node SN in the read or verify operation. For example, the fourth precharge voltage applied to the sensing node SN when the second test operation is performed may be lower than the third precharge voltage applied to the sensing node SN when the read or verify operation is performed.

For example, the reference voltage with which the test latch circuit 133a compares the voltage of the sensing node SN when the second test mode is performed may be higher than the reference voltage of the operation latch circuit 133b. For example, in the second test operation, the test latch circuit 133a may be configured to compare the voltage of the sensing node SN and a third reference voltage. For example, in the read or verify operation, the operation latch circuit 133b may be configured to compare the voltage of the sensing node SN and the second reference voltage. For example, the third reference voltage used in the second test operation may be higher than the second reference voltage used to sense the voltage change of the sensing node SN in the read or verify operation.

For example, when the second test mode is performed, the capacitance control circuit 134 may adjust the capacitance of the sensing node SN connected to the bit line BL. For example, the capacitance control circuit 134 may be configured to adjust the capacitance of the sensing node SN to a third capacitance in the second test operation. For example, in the read or verify operation, the capacitance control circuit 134 may be turned off. In this case, the capacitance of the sensing node SN may be the second capacitance. For example, the second capacitance may be higher than the third capacitance. For example, the capacitance control circuit 134 may adjust the capacitance of the sensing node SN to the third capacitance in the second test operation and may adjust the capacitance of the sensing node SN to the second capacitance greater than the third capacitance in the read or verify operation.

According to some implementations, when the second test mode is performed, the control logic circuit 160 may control the page buffer circuit 130-1 to use a sensing time longer than a sensing time used to sense a voltage change of the sensing node SN in the read or verify operation. For example, the page buffer circuit 130-1 may be configured to sense the voltage change of the sensing node SN under control of the control logic circuit 160. For example, the control logic circuit 160 may control a reference time being a time during which the page buffer circuit 130-1 senses the voltage change. For example, in the second test operation, the time during which the page buffer circuit 130-1 senses the voltage change may be a third time. For example, in the read or verify operation, the time during which the page buffer circuit 130-1 senses the voltage change may be the second time. For example, under control of the control logic circuit 160, the third time may be set to be longer than the second time. For example, the third time being a time which is used for the page buffer circuit 130-1 to sense the voltage change of the sensing node SN in the second test operation may be longer than the second time being a time which is used for the page buffer circuit 130-1 to sense the voltage change of the sensing node SN in the read or verify operation.

FIG. 12 is a diagram illustrating a change in a reference sensing current according to a change in a reference sensing time.

Referring to FIGS. 1, 5, 7, 8, and 12 together, according to some implementations, in the read or verify operation, the page buffer circuit 130-1 may be configured to sense a voltage change of the sensing node SN, based on a second reference sensing current I_sen2, at a time point ts2. For example, in the read or verify operation, the page buffer circuit 130-1 may be configured to compare the second reference voltage corresponding to the second reference sensing current I_sen2 with the voltage of the sensing node SN at the time point ts2.

According to some implementations, in the first test mode, the page buffer circuit 130-1 may be configured to sense the voltage change of the sensing node SN, based on a first reference sensing current I_sen1, at a time point ts1. For example, in the first test operation, the page buffer circuit 130-1 may be configured to compare the first reference voltage corresponding to the first reference sensing current I_sen1 with the voltage of the sensing node SN at the time point ts1.

According to some implementations, in the second test mode, the page buffer circuit 130-1 may be configured to sense the voltage change of the sensing node SN, based on a third reference sensing current I_sen3, at a time point ts3. For example, in the second test operation, the page buffer circuit 130-1 may be configured to compare the third reference voltage corresponding to the third reference sensing current I_sen3 with the voltage of the sensing node SN at the time point ts3.

According to the above description, different reference sensing currents may be used in the first test mode, the second test mode, and the read or verify operation. For example, the first reference sensing current I_sen1 may be larger than the second reference sensing current I_sen2, and the second reference sensing current I_sen2 may be larger than the third reference sensing current I_sen3.

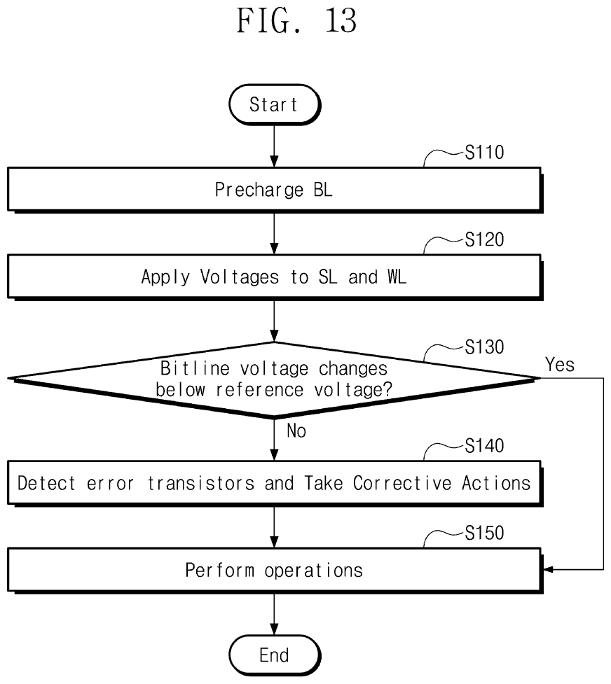

FIG. 13 is a flowchart for describing a test operation, according to some implementations of the present disclosure. The description will be given with reference to FIGS. 1, 5, and 7 together. For brevity of description, additional description associated with the components described above will be omitted to avoid redundancy.

In operation S110, the bit line BL and the sensing node SN may be precharged. For example, the page buffer circuit 130 may precharge the bit line BL and the sensing node SN with precharge voltages.

In operation S120, voltage may be applied to selection lines and word lines. For example, the row decoding circuit 120 may apply the test voltages to the selection lines and the dummy word lines and may apply the test voltages to the word lines. For example, the test voltage may include at least two different voltages. For example, the test voltages may be set depending on a threshold voltage distribution or threshold voltage distributions of selection transistors or dummy memory cells connected to the selection lines or dummy word lines.

In operation S130, the sensing node SN may be connected to the bit line BL, and whether the voltage of the sensing node SN is changed to a reference voltage or lower during a reference time may be sensed. For example, the page buffer circuit 130 may sense whether the precharged voltage of the sensing node SN is changed to the reference voltage or lower during the reference time. For example, when the voltage of the sensing node SN is changed to the reference voltage or lower, the page buffer circuit 130 may determine that the threshold voltage distribution or threshold voltage distributions of the selection transistors or dummy memory cells are normal. For example, when the voltage of the sensing node SN is not changed to the reference voltage or lower, the page buffer circuit 130 may determine that the threshold voltage distribution or threshold voltage distributions of the selection transistors or dummy memory cells are abnormal. For example, when the voltage of the sensing node SN is not changed to the reference voltage or lower, operation S140 may be performed. When the voltage of the sensing node SN is changed to the reference voltage or lower, operation S150 may be performed.

In operation S140, error transistors or error dummy memory cells may be detected, and corrective actions for the detected error transistors or error dummy memory cells may be performed. For example, the error transistors or error dummy memory cells may be transistors or dummy memory cells whose threshold voltage distribution or threshold voltage distributions are abnormal.

According to some implementations, the control circuits 120 to 170 may be configured to perform the test operation for each of transistors or dummy memory cells of a cell string determined as abnormal. For example, the control logic circuit 160 may control the page buffer circuit 130 to perform the test operation for each of the transistors or dummy memory cells of the cell string determined as abnormal. For example, the control logic circuit 160 may detect the error transistors or error dummy memory cells and may treat a memory block, in which the error transistors or error dummy memory cells are included, as a bad block. As another example, the control logic circuit 160 may treat the cell string, in which the error transistors or error dummy memory cells are included, as a bad cell string.

In operation S150, subsequent operations may be performed. For example, the control logic circuit 160 may perform the read, verify, program, or erase operation for the memory cell array 110 as a subsequent operation. For example, the control logic circuit 160 may terminate the test operation as the subsequent operation and may notify the external device that the test operation is terminated, through the second signal lines SIGL2 (refer to FIG. 1).

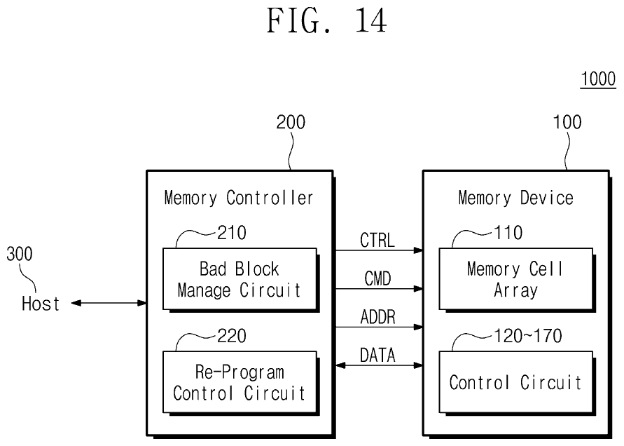

FIG. 14 is a diagram illustrating a storage device, according to some implementations of the present disclosure. For brevity of description, additional description associated with the components described above will be omitted to avoid redundancy.

A storage device 1000 may include a nonvolatile memory device 100 and a memory controller 200.

The nonvolatile memory device 100 may include components which are the same as or similar to those of the memory device 100 of FIG. 1. For example, the nonvolatile memory device 100 may include the memory cell array 110 and the control circuits 120 to 170, and the control circuits 120 to 170 may include the row decoding circuit 120, the page buffer circuit 130, the data input/output circuit 140, the buffer circuit 150, the control logic circuit 160, and the voltage generating circuit 170.

The memory controller 200 may be configured to control the nonvolatile memory device 100. For example, the memory controller 200 may be configured to control the nonvolatile memory device 100, based on a signal from a host 300. For example, the memory controller 200 may be configured to provide the control signal CTRL, the command CMD, and the address ADDR to the nonvolatile memory device 100 and to exchange the data “DATA” with the nonvolatile memory device 100 (refer to FIG. 1). For example, the memory controller 200 may control the control circuits 120 to 170 through the control signal CTRL, the command CMD, and the address ADDR. For example, through the control circuits 120 to 170, the memory controller 200 may perform an operation of reading or writing the data “DATA” from or in the memory cell array 110 or an operation of erasing the data “DATA” of the memory cell array 110.

The memory controller 200 may include a bad block manage circuit 210 and a re-program control circuit 220. According to some implementations, the control circuits 120 to 170 may perform the above-described first test operation (refer to FIG. 5) and the above-described second test operation (refer to FIG. 7) for the memory cell array 110 and may output a result of the test operations. For example, the control circuits 120 to 170 may output the result of the test operations to the memory controller 200.

Based on the result of the test operations, the bad block manage circuit 210 may be configured to treat a memory block in which the test operation is performed, as a bad memory block. For example, in the first test operation, when a channel path is not formed in a first cell string, the bad block manage circuit 210 may be configured to treat a memory block in which the first cell string is included, as a bad memory block. For example, referring to FIG. 5, when a result of performing the first test operation for the a-th cell string CSa indicates that a voltage of a sensing node connected to the first bit line BL1 is not changed to the first reference voltage or lower during the first time, the bad block manage circuit 210 may be configured to treat a first memory block as a bad memory block. For example, the bad block manage circuit 210 may be configured to manage memory blocks treated as a bad memory block. As another example, in the first test operation, when a channel path is not formed in the first cell string, the bad block manage circuit 210 may be configured to treat the first cell string as a bad cell string.

Based on the result of the test operations, the re-program control circuit 220 may be configured to again perform the program operation for a memory block in which a cell string experiencing the test operation is included or to copy data of the memory block including the cell string experiencing the test operation to any other memory block (i.e., to perform migration for the memory block).

According to some implementations, the re-program control circuit 220 may be configured to again program threshold voltages or threshold voltage distributions for error transistors or error dummy memory cells of the memory block in which the test operation is performed. For example, in the second test operation, when a channel path is formed in a cell string, the re-program control circuit 220 may be configured to program transistors or dummy memory cells in which the second test operation is performed. For example, referring to FIG. 7 together, when a result of performing the second test operation indicates that the voltage of the sensing node connected to the first bit line BL1 is changed to the reference voltage or lower for a given time, the re-program control circuit 220 may be configured to again perform the program operation for the n-th ground selection transistor GSTna of the a-th cell string CSa and the n-th ground selection transistor GSTnb of the b-th cell string CSb. For example, the re-program control circuit 220 may perform the program operation through the control circuits 120 to 170.

According to some implementations, the re-program control circuit 220 may be configured to migrate valid data of the first memory block experiencing the test operation to a second memory block. For example, as the first test operation or the second test operation for the first memory block is performed, that the threshold voltages or threshold voltage distributions of selection transistors or dummy memory cells in the first memory block are abnormal may be checked. In this case, there may be the risk of data loss in the first memory block. For example, the re-program control circuit 220 may be configured to migrate valid data of the first memory block to the second memory block and to then perform the erase operation for the first memory block.

According to the present disclosure, a memory device may include a plurality of memory blocks, and each of the plurality of the memory blocks may include a plurality of cell strings. The plurality of cell strings may be connected to a plurality of selection lines and a plurality of word lines. In a test operation, depending on a threshold voltage or threshold voltage distribution of each of selection transistors, the memory device may apply test voltages to the plurality of selection lines and may apply pass voltages to the plurality of word lines. A process by which the memory device senses a voltage change of a bit line to check threshold voltages or threshold voltage distributions of the selection transistors can be performed at high speed.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A memory device comprising:
a memory block including a plurality of cell strings connected to a bit line, wherein each of the plurality of cell strings includes
a plurality of selection transistors connected to a plurality of selection lines, and
a plurality of memory cells connected to a plurality of word lines;
a row decoding circuit configured to apply at least two different first test voltages to the plurality of selection lines and to apply pass voltages to the word lines, in a test operation; and
a control circuit including a sensing node,
wherein, in the test operation, the control circuit is configured to
connect the bit line and the sensing node during a first time after the at least two different first test voltages are applied, to sense whether a voltage of the sensing node is changed to a first reference voltage or lower; and
terminate the test operation or perform a subsequent operation following the test operation, based on sensing whether the voltage of the sensing node is changed to the first reference voltage or lower.

2. The memory device of claim 1, wherein the at least two different first test voltages are different from each other depending on a threshold voltage range in which the plurality of selection transistors are programmed.

3. The memory device of claim 1, wherein, based on the voltage of the sensing node exceeding the first reference voltage during the first time, the control circuit is configured to check, as the subsequent operation, a threshold voltage range of the plurality of selection transistors.

4. The memory device of claim 1, wherein the first time is shorter than a second time, wherein the control circuit is configured to sense a voltage change of the sensing node in a read or verify operation during the second time.

5. The memory device of claim 1, wherein the first reference voltage is lower than a second reference voltage, wherein the control circuit is configured to sense a voltage change of the sensing node in a read or verify operation based on the second reference voltage.

6. The memory device of claim 1, wherein, in the test operation, a capacitance of the sensing node connected to the bit line is configured to be a first capacitance, and wherein, in a read or verify operation, the capacitance of the sensing node connected to the bit line is configured to be a second capacitance that is smaller than the first capacitance.

7. The memory device of claim 1, wherein a page buffer circuit is configured to apply a first precharge voltage to the sensing node in the test operation, and to apply a second precharge voltage to the sensing node in a read or verify operation, wherein the first precharge voltage is higher than the second precharge voltage.

8. The memory device of claim 1, wherein each of the plurality of cell strings further includes a plurality of dummy memory cells connected to a plurality of dummy word lines, and
wherein, in the test operation, the row decoding circuit is configured to apply at least two different second test voltages to the dummy word lines.

9. The memory device of claim 1, wherein the plurality of cell strings are connected between the bit line and a common source line,
wherein the plurality of selection transistors includes a plurality of ground selection transistors connected to a plurality of ground selection lines, and
wherein, based on application of a selection voltage to the at least one ground selection line, at least one of ground selection transistor connected to at least one ground selection line from among the plurality of ground selection transistors is configured to be turned on, and at least another ground selection line is configured to be turned off.

10. An operation method of a memory device, the memory device comprising a sensing node, a bit line, a first cell string, and a second cell string connected to the bit line, the first cell string comprising first selection transistors and first memory cells and the second cell string comprising second selection transistors and second memory cells, the method comprising:
precharging the bit line and the sensing node;
applying at least two different test voltages to the first selection transistors and the second selection transistors;
applying pass voltages to the first memory cells and the second memory cells;
connecting the sensing node and the bit line to sense whether a voltage of the sensing node is changed to a first reference voltage or lower during a first time; and
performing a subsequent operation for the memory device, based on the sensing.

11. The method of claim 10, wherein, in a first test mode, applying the at least two different test voltages includes:
applying the at least two different test voltages to the first selection transistors; and
applying shut-off voltages to at least one of the second selection transistors.

12. The method of claim 11, wherein performing the subsequent operation comprises performing a test operation for each of the first selection transistors in response to the voltage of the sensing node exceeding the first reference voltage during the first time.

13. The method of claim 11, wherein the first time is shorter than a second time, the method comprising sensing a voltage change of the sensing node in a read or verify operation during the second time.

14. The method of claim 10, wherein, in a second test mode, applying at least two different test voltages comprises:
performing a test operation for a first transistor among the first selection transistors and for a second transistor among the second selection transistors; and
applying the pass voltages to remaining transistors among the first and second selection transistors.

15. The method of claim 14, wherein the first time is longer than a second time, the method comprising sensing a voltage change of the sensing node in a read or verify operation during the second time.

16. The method of claim 10, wherein the first selection transistors and the second selection transistors comprise dummy memory cells.

17. A storage device comprising:
a nonvolatile memory device including a plurality of memory blocks and a control circuit controlling the plurality of memory blocks; and
a memory controller configured to control the nonvolatile memory device,
wherein each of the plurality of memory blocks includes a plurality of cell strings,
wherein each of the plurality of cell strings includes a plurality of selection transistors connected to a plurality of selection lines and a plurality of memory cells connected to a plurality of word lines, and
wherein the control circuit is configured to:
apply at least two different test voltages to selection lines connected to a first cell string included in a first memory block among the plurality of memory blocks; and
apply pass voltages to word lines connected to the first cell string to check whether a channel path of the first cell string is formed.

18. The storage device of claim 17, wherein the memory controller includes a bad block manage circuit configured to treat the first memory block as a bad memory block, based on the channel path of the first cell string being formed.

19. The storage device of claim 17, wherein the memory controller includes a re-program control circuit configured to re-program threshold voltages of the selection transistors included in the first cell string, based on the channel path of the first cell string being formed.

20. The storage device of claim 19, wherein the re-program control circuit is configured to migrate valid data of the first memory block to a second memory block and to then perform an erase operation for the first memory block.
